(19) United States
(12) Patent Application Publication
(10) Pub. No.: US 2025/0316555 A1
(43) Pub. Date: Oct. 9, 2025

(54) POWER MODULE USING ELECTRICAL INSULATION FILM TO CONDUCT HEAT

(71) Applicant: Delta Electronics, Inc., Taoyuan City (TW)

(72) Inventors: Wen Shang LAI, Taoyuan City (TW); Han Lin WU, Taoyuan City (TW); Wei Chen TSENG, Taoyuan City (TW)

(21) Appl. No.: 19/055,683

(22) Filed: Feb. 18, 2025

(30) Foreign Application Priority Data
Apr. 9, 2024 (CN) 202410421062.3

(51) Int. Cl. H01L 23/367; H01L 23/00; H01L 23/31; H01L 23/538

(52) U.S. Cl. CPC H01L 23/3677; H01L 23/538; H01L 24/40; H01L 24/41; H01L 23/3121; H01L 2224/40137; H01L 2224/40227; H01L 2224/4118

(57) ABSTRACT

A power module using electrical insulation film to conduct heat is provided. The power module comprises an electrical insulation film, a heat sink, at least one base metal layer, at least one first semiconductor device, and a sealant. The electrical insulation film is made of an elastic material, and the electrical insulation film is formed on an upper surface of the heat sink. The base metal layer is formed on an upper surface of the electrical insulation film. The first semiconductor device is disposed on the base metal layer. The sealant is disposed on the heat sink. The electrical insulation film is placed on the heat sink for replacing the traditional ceramic substrate, thereby reducing the number of structural layers in the power module.

### CROSS REFERENCE TO RELATED APPLICATIONS

This application claims priority to China Application Serial Number 202410421062.3, filed on Apr. 9, 2024, which is incorporated herein by reference.

### FIELD OF INVENTION

The present disclosure relates to a power module, in particular to a power module using an electrical insulation film to conduct heat.

### BACKGROUND OF INVENTION

At present, power semiconductor devices are widely used. In higher power applications, module packaging is generally used. For widely used packaging, for example, a power module mainly includes power devices, metal plates, soldering layers, direct bonded copper ceramic substrates (DBC), insulating heat dissipation resin films or other insulating heat dissipation materials, metal wiring, electrical terminals, and epoxy resin.

The power devices of the power module are fixed to the insulating heat dissipation material through welding, electrically connected through metal wires, and then the ceramic substrate or other insulating heat dissipation material is placed on the metal plate through processes such as welding or sintering. The heat generated by the power devices passes through the ceramic substrate or other insulating heat dissipation materials and is conducted to the metal plate through the welding layer, the metal plate is dissipated through air cooling or water cooling, and the electrical terminals are used to connect external circuits.

However, the power devices of the power module are arranged on the upper copper foil of the ceramic substrate, The ceramic substrate is configured as an insulating layer, and the lower copper foil of the ceramic substrate is bonded to the heat sink through the laminating material. The heat dissipation path of the power device needs to go through a multi-layer structure, so that the heat of the power device can reach the outside for heat dissipation, thereby forming a high thermal resistance, making the heat dissipation effect of the power module poor. Moreover, the multi-layer structure of the power module has a complicated manufacturing process, and the thickness of the ceramic substrate cannot be effectively reduced, resulting in poor yield and high cost of the power module.

As a result, it is necessary to provide a power module using electrical insulation film to conduct heat to solve the problems existing in the conventional technologies, as described above.

### SUMMARY OF INVENTION

One object of the present disclosure is to provide a power module using an electrical insulation film to conduct heat. An electrical insulation film is disposed on a heat sink to replace the traditional ceramic substrate structure, thereby reducing the number of structural layers of the power module.

According to the aforementioned object, a power module using electrical insulation film to conduct heat is provided. The power module comprises an electrical insulation film, a heat sink, at least one base metal layer, at least one first semiconductor device, and a sealant, wherein the electrical insulation film is made of an elastic material. The electrical insulation film is formed on an upper surface of the heat sink. The base metal layer is formed on an upper surface of the electrical insulation film. The first semiconductor device is disposed on the base metal layer. The sealant is disposed on the heat sink to cover the electrical insulation film, the base metal layer, and the first semiconductor device.

According to an embodiment of the present disclosure, the power module further comprises a base, and the heat sink is disposed on the base.

According to an embodiment of the present disclosure, the heat sink and the base are integrally formed.

According to an embodiment of the present disclosure, a heat dissipation channel is formed between the heat sink and the base.

According to an embodiment of the present disclosure, the heat dissipation channel comprises a plurality of longitudinal grooves and a plurality of transverse grooves, and the longitudinal grooves and the transverse grooves are interlaced with each other.

According to an embodiment of the present disclosure, the heat sink comprises a body and a plurality of heat sink fins, the body comprises an upper surface and a lower surface opposite to each other, the heat sink fins are arranged on the lower surface of the body, and the electrical insulation film is formed on the upper surface of the body.

According to an embodiment of the present disclosure, the base comprises a recess, the heat sink fins are disposed in the recess, and one end of the heat sink fins is spaced apart from a surface of the recess.

According to an embodiment of the present disclosure, the base comprises a recess, the heat sink fins are disposed in the recess, and one end of the heat sink fins is connected to a surface of the recess.

According to an embodiment of the present disclosure, the power module further comprises a first interlayer metal layer covering a portion of an upper surface of the first semiconductor device and the electrical insulation film, and the first semiconductor device is electrically connected to the first interlayer metal layer and the base metal layer respectively.

According to an embodiment of the present disclosure, the power module further comprises a first interlayer film formed on an upper surface of the first interlayer metal layer.

According to an embodiment of the present disclosure, the power module further comprises a segment film formed on a portion of a lower surface of the first interlayer metal layer, and the segment film is configured to isolate the first semiconductor device.

According to an embodiment of the present disclosure, the power module further comprises a second interlayer metal layer formed above the first interlayer metal layer, and the second interlayer metal layer and the first interlayer metal layer are spaced apart from each other.

According to an embodiment of the present disclosure, at least one second semiconductor device is disposed on an upper surface of the second interlayer metal layer, and the second semiconductor device is located above the first semiconductor device.

According to an embodiment of the present disclosure, the plurality of first semiconductor devices and the plurality of second semiconductor devices of the power module are arranged correspondingly up and down.

According to an embodiment of the present disclosure, at least one second semiconductor device is disposed on an upper surface of the second interlayer metal layer, and the second semiconductor device is arranged in parallel with the first semiconductor device.

According to an embodiment of the present disclosure, the first interlayer film is formed between the first interlayer metal layer and the second interlayer metal layer.

According to an embodiment of the present disclosure, the power module further comprises a second interlayer film formed on a lower surface of the second interlayer metal layer.

According to an embodiment of the present disclosure, a gap is formed between the second interlayer film and the first interlayer film.

According to an embodiment of the present disclosure, the power module further comprises at least one top metal layer located above the second interlayer metal layer and covering at least one second semiconductor device, and the second semiconductor device is electrically connected to the top metal layer and the second interlayer metal layer respectively.

According to an embodiment of the present disclosure, the power module further comprises a top film formed on an upper surface of the top metal layer.

As described above, the power module of the present disclosure directly places the electrical insulation film on the heat sink, replacing the structure of the ceramic substrate, thus the number of structural layers of the power module can be reduced. The heat energy generated by the first semiconductor devices can quickly reach the heat dissipation channel to achieve better heat dissipation effect and extend product life, and the heat sink fins and the heat dissipation channel can be integrated to reduce the total number of parts of the power module. Moreover, The distance between the upper and lower layers of the power module can be shortened to reduce circuit stray inductance, thereby effectively reducing the oscillation peak voltage, improving power loss, and lowering temperature.

### DESCRIPTION OF DRAWINGS

FIG. 1 is a schematic view of a power module using electrical insulation film to conduct heat according to an embodiment of the present disclosure.

FIG. 2 is a schematic view of a heat dissipation channel of the power module using electrical insulation film to conduct heat according to an embodiment of the present disclosure.

FIG. 3 is a schematic view of another implementation aspect of the heat dissipation channel of the power module using electrical insulation film to conduct heat according to the embodiment of the present disclosure.

FIG. 4 is a schematic view of a heat dissipation channel of the power module using electrical insulation film to conduct heat according to another embodiment of the present disclosure.

FIG. 5 is a schematic view of another implementation aspect of the heat dissipation channel of the power module using electrical insulation film to conduct heat according to the embodiment of the present disclosure.

FIG. 6 is a schematic view of a heat dissipation channel of the power module using electrical insulation film to conduct heat according to further one embodiment of the present disclosure.

FIG. 7 is a schematic view of another implementation aspect of the heat dissipation channel of the power module using electrical insulation film to conduct heat according to the embodiment of the present disclosure.

FIG. 8 is a schematic view of a heat dissipation channel of the power module using electrical insulation film to conduct heat according to further one embodiment of the present disclosure.

### DETAILED DESCRIPTION OF PREFERRED EMBODIMENTS

In order to make the above and other objects, features, and advantages of the present disclosure more comprehensible, preferred embodiments of the present disclosure will be described below in detail together with the attached drawings. Furthermore, the directional terms used in the present disclosure, for example, up, down, top, bottom, front, back, left, right, inside, outside, side, around, central, horizontal, transverse, vertical, longitudinal, axial, radial direction, the uppermost layer, or the lowermost layer, etc. are only the directions shown in the attached drawings. Therefore, the directional terms are only used to illustrate and express the present disclosure, but not to limit the present disclosure.

Please refer to FIG. 1, a power module using electrical insulation film to conduct heat according to an embodiment of present disclosure is illustrated. The power module comprises an electrical insulation film 21, a heat sink 3, at least one base metal layer 41, at least one first semiconductor device 51, and a sealant 6. The detailed structure of each component, assembly relationships, and principles of operation in present disclosure will be described in detail hereinafter.

Please refer to FIG. 1, the electrical insulation film 21 is made of an elastic material. Specifically, the elastic material has functions of flexibility, high thermal conductivity, and high electrical insulation. In the embodiment, the elastic material is aluminum nitride oxide, its heat resistance is 1200° C., and the thickness of the electrical insulation film 21 is 10 um to 100 um.

Please refer to FIG. 1, the electrical insulation film 21 is formed on an upper surface of the heat sink 3. The heat sink 3 comprises a body 31 and a plurality of heat sink fins 32, wherein the body 31comprises an upper surface and a lower surface opposite to each other. The heat sink fins 32 are arranged on the lower surface of the body 31, and the electrical insulation film 21 is formed on the upper surface of the body. In the embodiment, the power module is provided with the electrical insulation film 21 on the upper surface of the body 31 of the heat sink 3. It allows the thickness of the power module to be effectively reduced, shortening the thermal conduction path, reducing thermal resistance, and helping to dissipate heat.

Please refer to FIG. 1, in the embodiment, the power module further comprises a base 7, and the heat sink 3 is disposed on the base 3. Specifically, the base 7 comprises a recess 71, the heat sink fins 32 are disposed in the recess 71, and one end of the heat sink fins 32 is spaced apart from a surface of the recess 71.

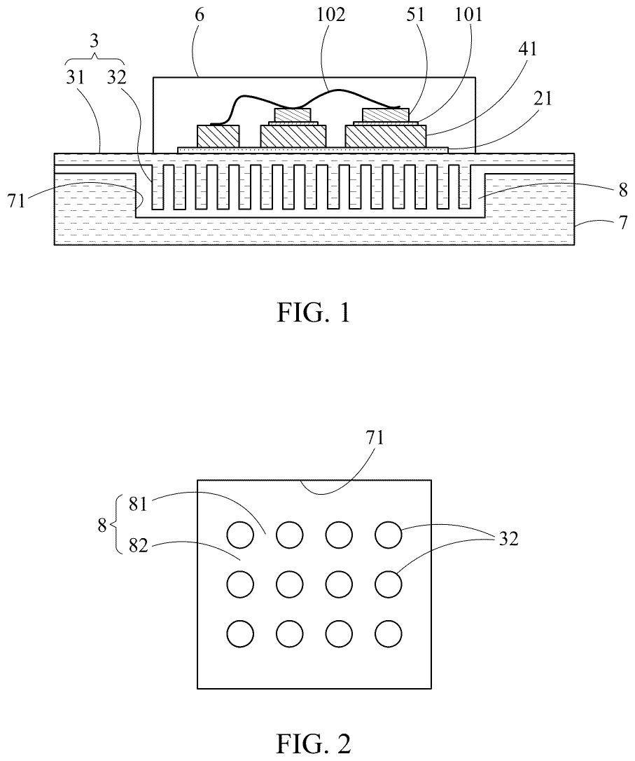

Please refer to FIG. 1 and FIG. 2, a heat dissipation channel 8 is formed between the heat sink 3 and the base 7. The heat dissipation channel 8 comprises a plurality of longitudinal grooves 81 and a plurality of transverse grooves 82, wherein the longitudinal grooves 81 and the transverse grooves 82 are interlaced with each other.

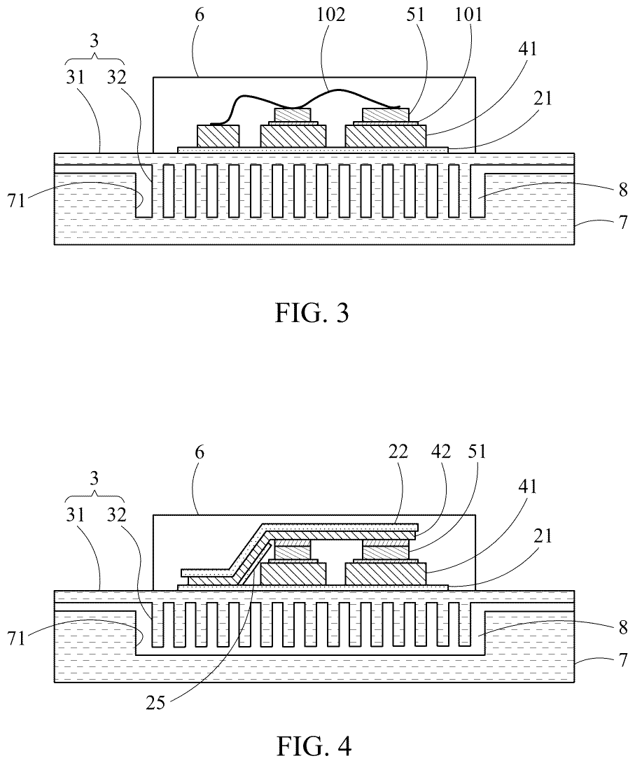

Please refer to FIG. 3, in other embodiments, the heat sink 7 and the base 3 are integrally formed. Specifically, the heat sink fins 32 are disposed in the recess 71, and one end of the heat sink fins 32 is connected to a surface of the recess 71. The heat dissipation channel 8 is configured for heat dissipation, and the heat sink fins 32 are also configured to support the first semiconductor devices 51. The heat sink fins 32 are integrated with the heat dissipation channel 8 to improve the heat dissipation capacity and structural strength of the power module.

Please refer to FIG. 1, in the embodiment, three base metal layers 41 of the power module are arrayed in parallel with each other and the base metal layers 41 are disposed on an upper surface of the electrical insulation film 21. The power module includes two first semiconductor devices 51, the first semiconductor devices 51 are arranged in parallel with each other, and the first semiconductor devices 51 are disposed on the corresponding base metal layer 41. The number of the base metal layers 41 is greater than the number of the first semiconductor devices 51, so that one of the base metal layers 41 is not provided with a corresponding first semiconductor device 51, and the base metal layer 41 is configured to be electrically connected to a bonding wire 102. Specifically, the first semiconductor devices 51 are electrically connected to the base metal layer 41 through the solder/sintered layer 101. The first semiconductor devices 51 are electrically connected through the bonding wires 102.

Please refer to FIG. 1 and FIG. 2, the sealant 6 is disposed on the heat sink 3 and the sealant 6 covers the electrical insulation film 21, the base metal layer 41, and the first semiconductor devices 51, so that the electrical insulation film 21, the base metal layer 41, and the first semiconductor devices 51 are wrapped in the sealant 6.

According to the above structure, the electrical insulation film 21 of the power module is arranged on the heat sink 3 and the base metal layer 41 carrying the first semiconductor devices 51 is disposed on the electrical insulation film 21. The electrical insulation film 21 can replace the traditional technology of directly cladding a copper ceramic substrate, and the electrical insulation film 21 is disposed on the heat sink 3.

As described above, the power module of the present disclosure directly places the electrical insulation film 21 on the heat sink 3, replacing the structure of the ceramic substrate, thus the number of structural layers of the power module can be reduced. The heat energy generated by the first semiconductor devices 51 can quickly reach the heat dissipation channel 8 to achieve better heat dissipation effect and extend product life, and the heat sink fins 32 and the heat dissipation channel 8 can be integrated to reduce the total number of parts of the power module. Moreover, The distance between the upper and lower layers of the power module can be shortened to reduce circuit stray inductance, thereby effectively reducing the oscillation peak voltage, improving power loss, and lowering temperature.

Please refer to FIG. 4, a power module using electrical insulation film to conduct heat according to another embodiment of present disclosure is illustrated. The embodiment generally uses the same component names and drawing numbers and the differences are as follows: the power module further comprises a first interlayer metal layer 42. The first interlayer metal layer 42 covers two first semiconductor devices 51 and a portion of an upper surface of the electrical insulation film 21, so that the first semiconductor devices 51 are electrically connected to the first interlayer metal layer 42 and the base metal layer 41 respectively.

In the embodiment, the first semiconductor devices 51 are respectively electrically connected to the first interlayer metal layer 42 and the base metal layer 41 through solder/sintered layers. Furthermore, the first interlayer metal layer 42 comprises a lower horizontal section connected to the upper surface of the electrical insulation film 21, an upper horizontal end covering the first semiconductor devices 51, and a curved section connected to the lower horizontal section and the upper horizontal end.

Please refer to FIG. 4, the power module further comprises a first interlayer film 22 and the first interlayer film 22 is formed on an upper surface of the first interlayer metal layer 42. Specifically, the first interlayer film 22 is also made of an elastic material, wherein the elastic material has functions of flexibility, high thermal conductivity, and high electrical insulation. In the embodiment, the elastic material is aluminum nitride oxide and the thickness of the first interlayer film 22 is 10 um to 100 um.

Please refer to FIG. 4, the power module further comprises a segment film 25, the segment film 25 is formed on a portion of a lower surface of the first interlayer metal layer 42, and the segment film 25 is configured to isolate the corresponding first semiconductor device 51. In the embodiment, the segment film 25 is formed on the lower surface of the curved section of the first interlayer metal layer 42.

In the embodiment, the base 7 comprises a recess 71, the heat sink fins 32 are disposed in the recess 71, and one end of the heat sink fins 32 is spaced apart from a surface of the recess 71.

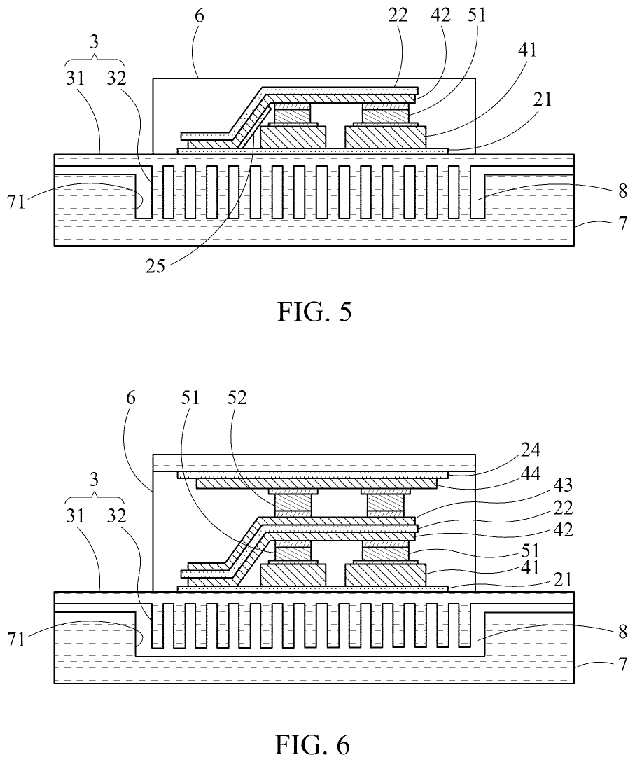

Please refer to FIG. 5, in other embodiments, the heat sink 7 and the base 3 are integrally formed. Specifically, the heat sink fins 32 are disposed in the recess 71, and one end of the heat sink fins 32 is connected to a surface of the recess 71.

As described above, the power module of the present disclosure uses a structural layer composed of the first interlayer metal layer 42 and the first interlayer film 22 to replace the wiring in the above embodiment, wherein the copper area for current conduction of the first interlayer metal layer 42 is increased to help spread heat along a horizontal direction. The structural layer composed of the first interlayer metal layer 42 and the first interlayer film 22 can shorten the current path of the power module to transmit signals, reduce parasitic inductance, and improve power loss.

Please refer to FIG. 6, a power module using electrical insulation film to conduct heat according to further one embodiment of present disclosure is illustrated. The embodiment generally uses the same component names and drawing numbers and the differences are as follows: the power module further comprises a second interlayer metal layer 43, the second interlayer metal layer 43 is formed above the first interlayer metal layer 42, and the second interlayer metal layer 43 and the first interlayer metal layer 42 are spaced apart from each other.

Please refer to FIG. 6, two second semiconductor devices 52 are disposed on an upper surface of the second interlayer metal layer 43 and the second semiconductor devices 52 are located above the first semiconductor devices 51. In the embodiment, the two first semiconductor devices 51 and the two second semiconductor devices 52 of the power module are arranged correspondingly up and down.

Please refer to FIG. 6, the first interlayer film 22 is formed between the first interlayer metal layer 42 and the second interlayer metal layer 43. In the embodiment, the first interlayer metal layer 42 is attached to the lower surface of the first interlayer film 22 and the second interlayer metal layer 43 is attached to the upper surface of the first interlayer film 22.

Please refer to FIG. 6, the power module further comprises at least a top metal layer 44 and the top metal layer 44 is located above the second interlayer metal layer 43. The top metal layer 44 covers the second semiconductor devices 52, so that the second semiconductor devices 52 are electrically connected to the top metal layer 44 and the second interlayer metal layer 43 respectively. In the embodiment, the second semiconductor devices 52 are electrically connected to the top metal layer 44 and the second interlayer metal layer 43 respectively through solder/sintered layers.

Please refer to FIG. 6, the power module further comprises a top film 24 and the top film 24 is formed on an upper surface of the top metal layer 44. Specifically, the top film 24 is also made of an elastic material, wherein the elastic material has functions of flexibility, high thermal conductivity, and high electrical insulation. In the embodiment, the elastic material is aluminum nitride oxide and the thickness of the top film 24 is 10 um to 100 um.

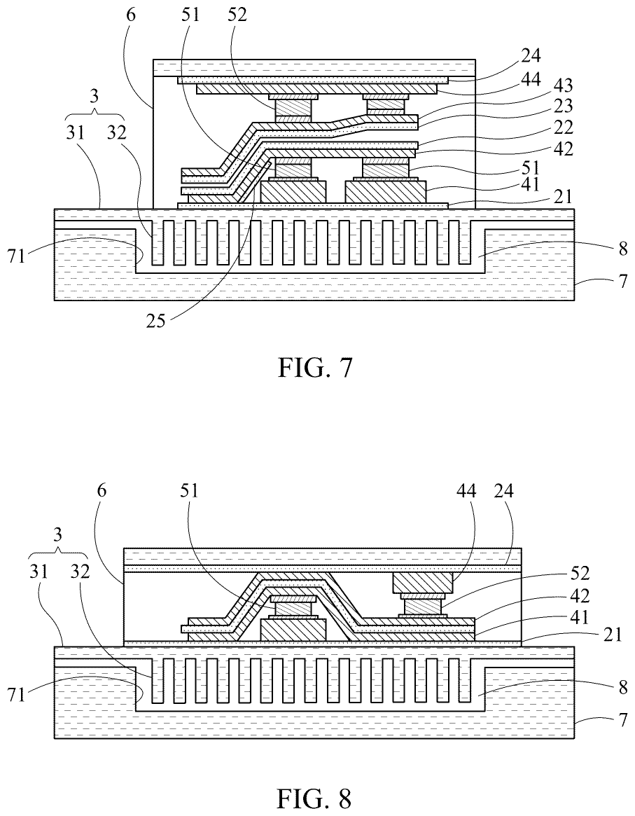

Please refer to FIG. 7, in other embodiments, the power module further comprises a second interlayer film 23 and the second interlayer film 23 formed on a lower surface of the second interlayer metal layer 43. Specifically, the second interlayer film 23 is also made of an elastic material, wherein the elastic material has functions of flexibility, high thermal conductivity, and high electrical insulation. In the embodiment, the elastic material is aluminum nitride oxide and the thickness of the second interlayer film 23 is 10 um to 100 um. Furthermore, a gap is formed between the second interlayer film 23 and the first interlayer film 22.

Please refer to FIG. 6, the segment film 25 of the power module is formed on a portion of a lower surface of the first interlayer metal layer 42 and the segment film 25 is formed on the lower surface of the curved section of the first interlayer metal layer 42. Specifically, the segment film 25 is also made of an elastic material, wherein the elastic material has functions of flexibility, high thermal conductivity, and high electrical insulation. In the embodiment, the elastic material is aluminum nitride oxide and the thickness of the segment film 25 is 10 um to 100 um. Furthermore, a gap is formed between the second interlayer film 23 and the first interlayer film 22.

As described above, the power module of the present disclosure is provided with the top metal layer 44 located above to increase the heat dissipation path, form a heat dissipation function between the upper layer and the lower layer, and effectively improve the heat dissipation efficiency. Moreover, a structural layer composed of the first interlayer metal layer 42 and the first interlayer film 22 replaces the wiring in the above embodiment, wherein the copper area for current conduction of the first interlayer metal layer 42 is increased to help spread heat along a horizontal direction. The structural layer composed of the first interlayer metal layer 42 and the first interlayer film 22 can shorten the current path of the power module to transmit signals, reduce parasitic inductance, and improve power loss.

Please refer to FIG. 8, a power module using electrical insulation film to conduct heat according to further one embodiment of present disclosure is illustrated. The embodiment generally uses the same component names and drawing numbers and the differences are as follows: a second semiconductor device 52 is disposed on an upper surface of the second interlayer metal layer 43 and the second semiconductor device 52 is disposed in parallel with the first semiconductor device 51.

The top metal layer 44 of the power module is located above the first interlayer metal layer 42. The top metal layer 44 covers the second semiconductor device 52, so that the second semiconductor device 52 is electrically connected to the top metal layer 44 and the first interlayer metal layer 42 respectively. In the embodiment, the second semiconductor device 52 is electrically connected to the top metal layer 44 and the first interlayer metal layer 42 through solder/sintered layers respectively.

As described above, the power module of the present disclosure arranges the second semiconductor device 52 and the first semiconductor device 51 in parallel, which can reduce the number of layers of the power module, decrease the size of the power module, and increase its power density. Moreover, the power module is provided with the top metal layer 44 located above to increase the heat dissipation path, form a heat dissipation function between the upper layer and the lower layer, and effectively improve the heat dissipation efficiency. Furthermore, a structural layer composed of the first interlayer metal layer 42 and the first interlayer film 22 replaces the wiring in the above embodiment, wherein the copper area for current conduction of the first interlayer metal layer 42 is increased to help spread heat along a horizontal direction. The structural layer composed of the first interlayer metal layer 42 and the first interlayer film 22 can shorten the current path of the power module to transmit signals, reduce parasitic inductance, and improve power loss.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the invention. In view of the foregoing, it is intended that the present disclosure cover modifications and variations of this invention provided they fall within the scope of the following claims.

1. A power module using electrical insulation film to conduct heat, comprising:
an electrical insulation film made of an elastic material;
a heat sink, wherein the electrical insulation film is formed on an upper surface of the heat sink;
at least one base metal layer formed on an upper surface of the electrical insulation film;
at least one first semiconductor device disposed on the base metal layer; and
a sealant disposed on the heat sink to cover the electrical insulation film, the base metal layer, and the first semiconductor device.

2. The power module according to claim 1, wherein the power module further comprises a base, and the heat sink is disposed on the base.

3. The power module according to claim 2, wherein the heat sink and the base are integrally formed.

4. The power module according to claim 2, wherein a heat dissipation channel is formed between the heat sink and the base.

5. The power module according to claim 4, wherein the heat dissipation channel comprises a plurality of longitudinal grooves and a plurality of transverse grooves, and the longitudinal grooves and the transverse grooves are interlaced with each other.

6. The power module according to claim 2, wherein the heat sink comprises a body and a plurality of heat sink fins, the body comprises an upper surface and a lower surface opposite to each other, the heat sink fins are arranged on the lower surface of the body, and the electrical insulation film is formed on the upper surface of the body.

7. The power module according to claim 6, wherein the base comprises a recess, the heat sink fins are disposed in the recess, and one end of the heat sink fins is spaced apart from a surface of the recess.

8. The power module according to claim 6, wherein the base comprises a recess, the heat sink fins are disposed in the recess, and one end of the heat sink fins is connected to a surface of the recess.

9. The power module according to claim 1, wherein the power module further comprises a first interlayer metal layer covering a portion of an upper surface of the first semiconductor device and the electrical insulation film, and the first semiconductor device is electrically connected to the first interlayer metal layer and the base metal layer respectively.

10. The power module according to claim 9, wherein the power module further comprises a first interlayer film formed on an upper surface of the first interlayer metal layer.

11. The power module according to claim 9, wherein the power module further comprises a segment film formed on a portion of a lower surface of the first interlayer metal layer, and the segment film is configured to isolate the first semiconductor device.

12. The power module according to claim 9, wherein the power module further comprises a second interlayer metal layer formed above the first interlayer metal layer, and the second interlayer metal layer and the first interlayer metal layer are spaced apart from each other.

13. The power module according to claim 12, wherein at least one second semiconductor device is disposed on an upper surface of the second interlayer metal layer, and the second semiconductor device is located above the first semiconductor device.

14. The power module according to claim 13, wherein the plurality of first semiconductor devices and the plurality of second semiconductor devices of the power module are arranged correspondingly up and down.

15. The power module according to claim 12, wherein at least one second semiconductor device is disposed on an upper surface of the second interlayer metal layer, and the second semiconductor device is arranged in parallel with the first semiconductor device.

16. The power module according to claim 12, wherein the first interlayer film is formed between the first interlayer metal layer and the second interlayer metal layer.

17. The power module according to claim 12, wherein the power module further comprises a second interlayer film formed on a lower surface of the second interlayer metal layer.

18. The power module according to claim 17, wherein a gap is formed between the second interlayer film and the first interlayer film.

19. The power module according to claim 12, wherein the power module further comprises at least one top metal layer located above the second interlayer metal layer and covering at least one second semiconductor device, and the second semiconductor device is electrically connected to the top metal layer and the second interlayer metal layer respectively.

20. The power module according to claim 19, wherein the power module further comprises a top film formed on an upper surface of the top metal layer.
